(19) United States
(12) Patent Application Publication
(10) Pub. No.: US 2008/0131788 A1
(43) Pub. Date: Jun. 5, 2008

(54) METHOD TO AUTOMATICALLY REPAIR TRIM PHOTOMASK DESIGN RULE VIOLATIONS FOR ALTERNATING PHASE SHIFT LITHOGRAPHY

(76) Inventor: Carl Albert Vickery, Garland, TX (US)

Correspondence Address: TEXAS INSTRUMENTS INCORPORATED, P O BOX 655474, M/S 3999, DALLAS, TX, 75265, US

(21) Appl. No.: 11/565,161

(22) Filed: Nov. 30, 2006

(51) Int. Cl. G03F 1/00

(52) U.S. Cl. 430/5

(57) ABSTRACT

In accordance an embodiment of the invention, there is provided a method of designing a lithography mask. The method can comprise identifying an area of a layout to be formed on a substrate by exposing a phase photomask that comprises a phase aperture to a beam and trimming a portion of the area, wherein the area to be trimmed is located under the phase aperture and creating a notch in a portion of the area on the layout.

### FIELD OF THE INVENTION

This invention relates generally to the field of integrated circuits and more specifically to a method and system for optimized treatment of photomask data for alternating phase shift lithography.

### BACKGROUND OF THE INVENTION

Conventional optical projection lithography has been the standard silicon patterning technology for the past 20 years. It is an economical process due to its inherently high throughput, thereby providing a desirable low cost per part or die produced. A considerable infrastructure (including steppers, photomasks, resists, metrology, etc) has been built up around this technology.

In this process, a mask, or “reticle”, includes a semiconductor circuit layout pattern typically formed of opaque chrome, on a transparent glass (typically SiO₂) substrate. A stepper includes a light source and optics/lenses that project light coming through the reticle and images the circuit pattern, typically with a 4× to 5× reduction factor, on a photo-resist film formed on a silicon wafer. The term “chrome” refers to an opaque masking material that is typically but not always comprised of chrome. The transmission of the opaque material may also vary such as in the case of an attenuating phase shift mask.

As the semiconductor industry continues to evolve, feature sizes of the pattern are driven to smaller resolution. To meet this demand, Resolution-Enhanced optical lithography Technologies (“RET”) have become popular as techniques for providing patterns with sub-wavelength resolution. These methods include off-axis illumination (“OAI”), optical proximity correction (“OPC”), and phase-shift masks (“PSMs”). Such resolution-enhanced optical lithography methods are especially useful for generating physical devices on a wafer that require small size and tight design tolerance. Examples of such physical devices are the gate length of a transistor or the dimensions of contact cuts formed in inter-layer dielectrics.

One of the most common commercial implementations of phase shift mask technology is the double exposure method. In this method, the critical features are imaged using a phase shift photomask (“phase photomask”) and the non-critical and trim features are imaged in a second exposure using a conventional chrome-on-glass mask, such as a trim photomask.

An example of a double exposure phase shift method is illustrated in FIGS. 1A-1C. In this method, fine features 12 are imaged on a substrate 14, shown in FIG. 1A, in the first exposure, using a phase shift photomask 20 shown in FIG. 1B. Definition of other features 112 and trimming of undesired phase edges are performed in a second exposure using a trim photomask 120 shown in FIG. 1C. The phase shift photomask 20 may contain additional opaque features 18.

A typical double exposure phase shift method uses a chrome-on-glass binary photomask for the trim photomask 120. In this case, chrome regions 122 on the trim photomask 120 prevent desired features produced by the phase shift photomask 20 from being exposed in the trim exposure.

Problems arise, however, when using the dual exposure method. Indeed, some of the most common design rule violations for alternating phase shift lithography is in the spacing between the trim ‘wings’ on either side of a transistor, under the phase aperture, and nearby field polysilicon regions. Quite often, the field polysilicon at these locations is a wide polygon of polysilicon (‘poly’) used to locate a contact. This case accounts for a substantial number of phase shift related design rule violations.

Accordingly, the present invention solves these and other problems of the prior art to provide a method that can automatically repair trim mask design rule violations for alternating phase shift lithography.

### SUMMARY OF THE INVENTION

In accordance an embodiment of the invention, there is provided a method of designing a lithography mask. The method can comprise identifying an area of a layout to be formed on a substrate by exposing a phase photomask that comprises a phase aperture to a beam and trimming a portion of the area, wherein the area to be trimmed is located under the phase aperture and creating a notch in a portion of the area on the layout.

In accordance with another embodiment of the invention, there is provided a method of designing a lithography mask. The method can comprise identifying an area under a phase aperture to be trimmed having a design rule violation between the area under the phase aperture to be trimmed and a drawn region, creating a notch in the drawn region, and determining whether the drawn region having the notch violates the design rule.

In accordance with another embodiment of the invention, there is provided a computer readable medium comprising program code that configures a processor to perform a method of correcting a lithography mask. The computer readable medium can comprise program code for identifying an area of a layout to be formed on a substrate by exposing a phase photomask that comprises a phase aperture to a beam and trimming a portion of the area, wherein the area to be trimmed is located under the phase aperture. The computer readable medium can also comprise program code for creating a notch in a portion of the area on the layout.

Additional advantages of the embodiments will be set forth in part in the description which follows, and in part will be obvious from the description, or may be learned by practice of the invention. The advantages will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate embodiments of the invention and together with the description, serve to explain the principles of the invention.

### BRIEF DESCRIPTION OF THE DRAWINGS

FIG. 1A is a diagram illustrating a substrate formed using a conventional double exposure method;

FIG. 1B. is a diagram illustrating a phase shift photomask in a conventional double exposure method;

FIG. 1C is a diagram illustrating a trim photomask in a conventional double exposure method;

FIG. 2 is a flowchart illustrating one embodiment of a method for repairing trim photomask design rule violations;

FIG. 3A illustrates a portion of a phase photomask and a substrate according to the present teachings;

FIG. 3B illustrates a portion of the substrate shown in FIG. 3A at a further step in fabrication according to the present teachings;

FIG. 3C illustrates a portion of a trim photomask and the substrate shown in FIG. 3B at a further step in fabrication according to the present teachings; and

FIG. 4 illustrates a system for designing and correcting a photomask according to the present teachings.

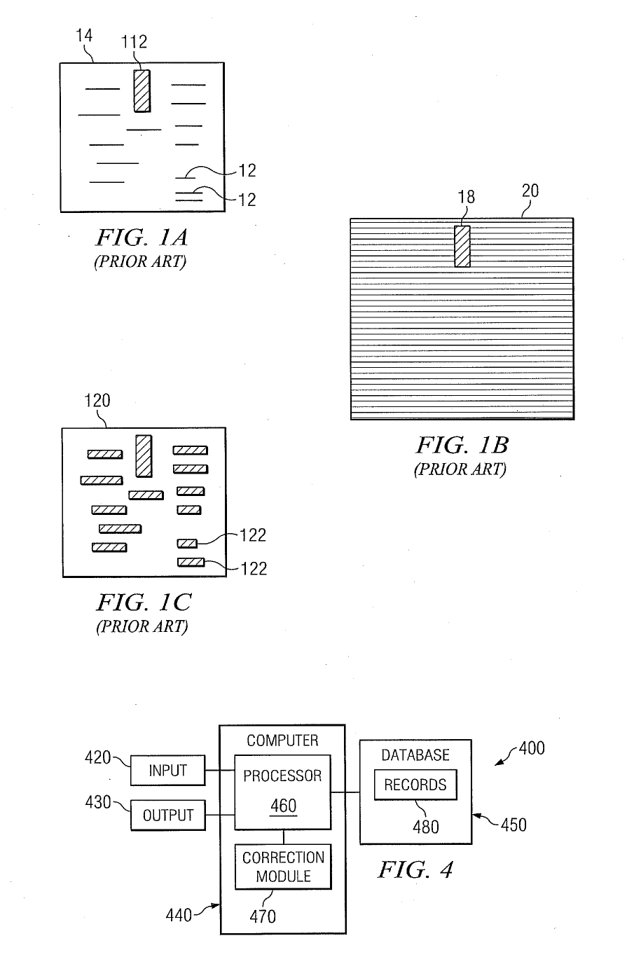

### DESCRIPTION OF THE EMBODIMENTS

Reference will now be made in detail to the present embodiments, examples of which are illustrated in the accompanying drawings. Wherever possible, the same reference numbers will be used throughout the drawings to refer to the same or like parts.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

As is well known in the art, both trim and phase masks are often used in double exposure methods. Critical features are generally imaged using a phase shift mask, and the non-critical and trim features are imaged in a second exposure using a trim mask. In regions where integrated circuit patterns are formed with a phase mask, such as the case of patterning integrated circuit feature, the trim mask may comprise one or more trim wings. Trim wings are patterns on the trim mask that protect the regions patterned by the phase mask from being imaged during the trim mask exposure.

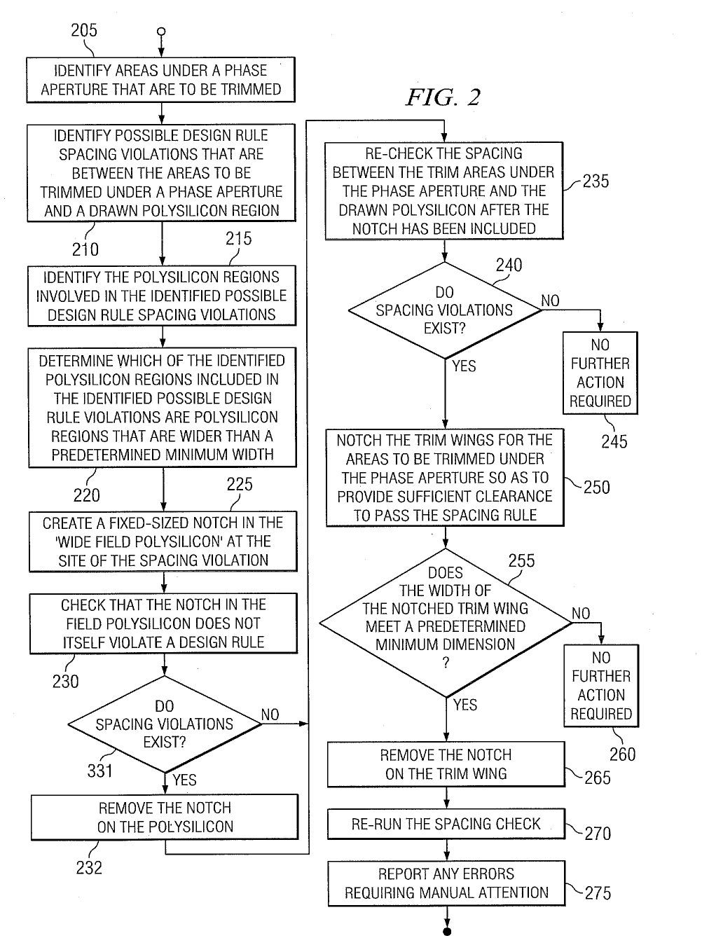

Embodiments of the present invention and its advantages are best understood by referring to FIG. 2 through FIG. 4 of the drawings, like numerals being used for like and corresponding parts of the various drawings.

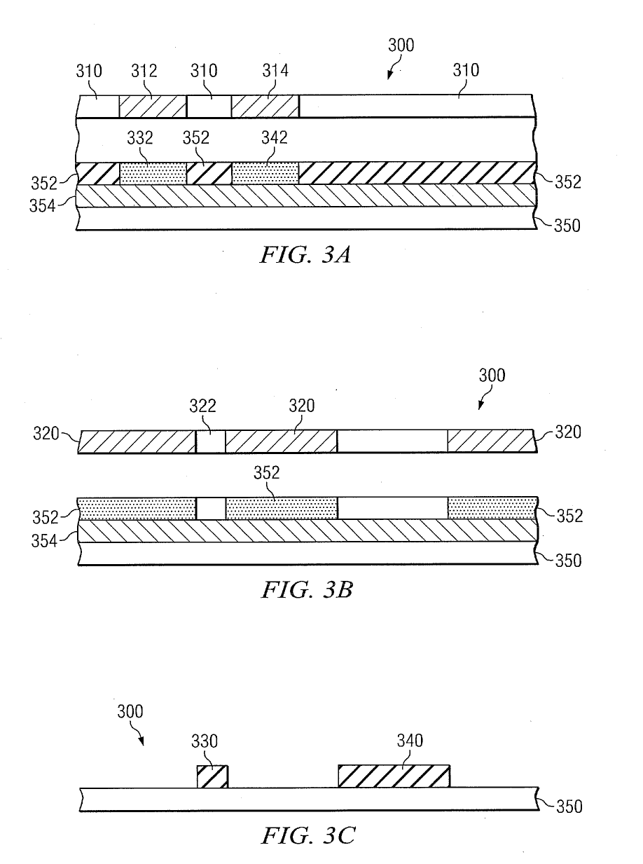

FIG. 2 is a flowchart 200 illustrating one embodiment of a method for correcting a photomask pattern. At 205 the method includes identifying areas under apertures of a phase photomask that are to be trimmed using a trim photomask. FIGS. 3A-3D are provided as an illustrative example of areas under a phase photomask that are to be trimmed using a trim photomask. For example, in FIG. 3A a phase photomask 310 used in conjunction with trim photomask 320, shown in FIG. 3B, to form various features, such as a transistor gate 330 and a field poly 340, on a substrate 350 shown in FIG. 3C. As shown in FIG. 3A the phase photomask 310 can include multiple apertures, such as apertures 312 and 314. Light is directed through the apertures 312 and 314 in the phase photomask 310 to form the transistor gate 330 on the substrate 350. For example, light passes through the apertures 312 and 314 to expose portions 332 and 342 of a photoresist 352 deposited on a poly layer 354 on the substrate 350.

In FIG. 3B the trim photomask 320 is used to trim, or reduce the size of, various features formed from the photoreist on the substrate 350 by the phase photomask 310. In FIG. 3C, the transistor gate 330 is trimmed using the trim wings 322 in the trim photomask 320 shown in FIG. 3C. In contrast, however, the field poly 340 is not trimmed. As will be appreciated by one of ordinary skill in the art, this correlates to the area (the transistor gate 330) between the apertures 312 and 314, which is trimmed, while the field poly 340 is not trimmed. Thus, in FIG. 3C, the transistor gate 330 has been trimmed. Correspondingly, at 205 in the flowchart 200 in FIG. 2, the transistor gate 330 is identified as an area between the phase photomask apertures 312 and 314 that are trimmed.

At 210, the method identifies possible design rule spacing violations (“DRSV”) such as those that may occur between the areas to be trimmed under a phase photomask aperture and a drawn area. Using FIGS. 3A-3C as an illustrative example, the method checks whether there is a DRSV in the space between the transistor gate 330, which is to be trimmed, and the field poly 340.

At 215, the method identifies the regions, such as the field poly region 340, that are involved in the possible DRSV. Then at 220, the method determines which of the regions identified at step 215 are wider than a predetermined minimum width. The predetermined minimum width can be specified by the designer or a fabrication facility. In many cases, these regions are part of a polysilicn ‘landing pad’ such as a contact polygon.

At 225, fixed-sized notches are created in the regions identified at step 215 that are wider than the predetermined minimum width. The notches can be placed on the identified regions at the site of the spacing violation. The size of the notch can be set by the designer or the fabrication facility and can be determined, either empirically or by simulation, to be small enough that it cannot resolve on the substrate. In practice, the notch has almost no impact on the final device, but can provide more clearance to try to meet the photomask spacing design rules.

At 230, the method checks whether a notch applied to the identified regions does not itself, create a design rule violation. For example, the method checks whether the notch applied to the field poly causes a design rule spacing violation. At 231, the method checks whether spacing violations exist. If spacing violations exist, then as shown in 231, the notch on the polysilicon can be removed. If no spacing violations exist, the method proceeds to 235.

Then at step 235, the method re-checks the spacing between the areas to be trimmed that are under the apertures in the phase photomask and the drawn regions after the notches have been added. As shown at 240, the method checks for DRSV after the notches have been added. If no DRSV are found, then no further action of the method is needed, as shown at step 245. If DRSV are found, then, as shown at step 250, notches can be added to trim wings in an attempt to remove the DRSV. For example, when DRSV are found, notches can be placed on trim wings 322, which are under the aperture 312, shown in FIGS. 3A and 3C. Notching the trim wings can provide sufficient clearance so that the design rules are not violated.

At step 255, the method determines whether the width of the notched trim wings meet a predetermined minimum dimension. The predetermined minimum dimension for the trim wings can be determined by, for example, the designer or the fabrication facility. Notched trim wings that meet the predetermined minimum dimension requirement need no further action, as shown at step 260. Notched trim wings that violate the predetermined minimum dimension are removed, as shown at step 260. Subsequently, at step 270, the method runs a spacing check for design rule violations. Any violations can be reported for manual attention, as shown at step 275.

FIG. 4 illustrates a system 400 for designing and correcting a mask pattern, such as a pattern on a phase photomask and/or a trim photomask. System 400 includes an input device 420 and an output device 430 coupled to a computer 440, which is in turn coupled to a database 450. Input device 420 may comprise, for example, a keyboard, a mouse, or any other device suitable for transmitting data to computer 440. Output device 430 may comprise, for example, a display, a printer, or any other device suitable for outputting data received from computer 440.

Computer 440 may comprise a personal computer, workstation, network computer, wireless computer, or one or more microprocessors within these or other devices, or any other suitable processing device. Computer 440 may include a processor 460 and a correction module 470. Processor 460 controls the flow of data between input device 420, output device 430, database 450, and correction module 470. Correction module 470 may receive descriptions of a contour and an uncorrected pattern and can compute a corrected pattern that maybe used to define the contour.

Database 450 may comprise any suitable system for storing data. Database 450 may store records 480 that include data associated with the contour, uncorrected pattern, and corrected pattern. A record 480 may be associated with a segment of the pattern.

While the examples given have been with respect to patterning transistor gates over diffusion regions, the methods and systems described herein may also be used to correct patterns of other layers of integrated circuits. For example, the interconnect parts of a metal pattern may be divided into base and relational segments for improved critical dimension correction, leaving the corners and contact/via pads to be corrected as traditional placement-correction segments.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.”

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of designing a lithography mask, the method comprising:
identifying an area of a layout to be formed on a substrate by exposing a phase photomask that comprises a phase aperture to a beam and trimming a portion of the area, wherein the area to be trimmed is located under the phase aperture; and
creating a notch in a portion of the area on the layout.

2. The method of designing a lithography mask according to claim 1, wherein the area violates a design rule before the notch is created in the area.

3. The method of designing a lithography mask according to claim 1 further comprising:
checking whether the area violates a design rule after the notch is created in the area.

4. The method of designing a lithography mask according to claim 3 further comprising:
creating a notch in a trim wing of a trim photomask so that the area passes a space rule.

5. The method of designing a lithography mask according to claim 1, wherein the area corresponds to a spacing of a semiconductor device located between a trim wing adjacent to a transistor and a field region.

6. The method of designing a lithography mask according to claim 5, wherein the field region comprises polysilicon.

7. A method of designing a lithography mask, the method comprising:
identifying an area under a phase aperture to be trimmed having a design rule violation between the area under the phase aperture to be trimmed and a drawn region;
creating a notch in the drawn region; and
determining whether the drawn region having the notch violates the design rule.

8. The method of designing a lithography mask according to claim 7 further comprising:
determining whether a spacing between the area under the phase aperture to be trimmed and a drawn region violates a spacing rule.

9. The method of designing a lithography mask according to claim 7, wherein the drawn region comprises a polysilicon region.

10. The method of designing a lithography mask according to claim 7, wherein the drawn region comprises a field region.

11. The method of designing a lithography mask according to claim 7 further comprising:
creating a notch in a trim wing of a trim photomask so that the area passes a space rule.

12. The method of designing a lithography mask according to claim 1 further comprising:
determining whether the trim wing having the notch violates the design rule.

13. A computer readable medium comprising program code that configures a processor to perform a method of correcting a lithography mask comprising:
program code for identifying an area of a layout to be formed on a substrate by,
exposing a phase photomask that comprises a phase aperture to a beam and trimming a portion of the area, wherein the area to be trimmed is located under the phase aperture; and
program code for creating a notch in a portion of the area on the layout.

14. The computer readable medium comprising program code according to claim 13, wherein the area violates a design rule before the notch is created in the area.

15. The computer readable medium comprising program code according to claim 13 further comprising:
program code for checking whether the area violates a design rule after the notch is created in the area.

16. The computer readable medium comprising program code according to claim 13 further comprising:
program code for creating a notch in a trim wing of a trim photomask so that the area passes a space rule.

17. The computer readable medium comprising program code according to claim 13, wherein the area corresponds to a spacing of a semiconductor device located between a trim wing adjacent to a transistor and a field region.

18. The computer readable medium comprising program code according to claim 13, wherein the field region comprises polysilicon.
